(19) United States
(12) Patent Application Publication
(10) Pub. No.: US 2025/0187909 A1
(43) Pub. Date: Jun. 12, 2025

(54) MICRO-ASSEMBLER SYSTEM WITH MICRO-OBJECT TRAP LOCATIONS

(71) Applicant: Xerox Corporation, Norwalk, CT (US)

(72) Inventors: Jeng PING LU, Freemont, CA (US); Sourobh RAYCHAUDHURI, Mountain View, CA (US); Eugene Michael CHOW, Palo Alto, CA (US)

(21) Appl. No.: 18/535,295

(22) Filed: Dec. 11, 2023

(51) Int. Cl. B81C 99/00

(52) U.S. Cl. CPC B81C 99/002; B81C 99/003

(57) ABSTRACT

What is disclosed is a micro-assembler backplane that has a backplane having a first surface and a number of controlled electrodes, wherein each is selectively activatable to manipulate micro-objects on the backplane. The micro-assembler backplane also has at least one trap location that is separate from the controlled electrodes. The at least one trap location is configured to hold, independently of activation of the controlled electrodes, at least one micro-object that is manipulated into a trap location.

### TECHNICAL FIELD

The present invention is directed to assembly apparatuses used to assemble micro-objects, and more particularly, to devices incorporating electrostatic fields to manipulate and hold the position of micro-objects on a surface.

### BACKGROUND

Electrostatic micro-assembler technology that includes a dynamic electrostatic electrode actuator array is a technique used to arrange micro-objects, such as microchips of various types, into a defined arrangement on a backplane according to a design of an apparatus being assembled. This electrode actuator array includes a number of electrodes that are selectively activated to produce an arrangement of time varying electrostatic field across the electrode array that are able to cause micro-objects to move or be fixed into particular locations using electrophoretic or dielectrophoretic force induced by electrostatic fields generated across the dynamic electrostatic electrode actuator array. The present locations of these micro-objects are monitored as they are moved by the electrostatic fields and an electric field to be generated across the dynamic electrostatic electrode actuator array that will move the micro-objects to their next location is calculated, based on those present locations, and then created by a subsequent selective activation of electrodes. This iterative generation of different electrostatic fields by the dynamic electrostatic electrode actuator array continues until all the micro-objects are located in their desired locations as defined by the structure being assembled.

### BRIEF SUMMARY

What is disclosed is a micro-assembler backplane arrangement that has a backplane with a first surface and a number of control electrodes wherein each controlled electrode is selectively activatable to manipulate micro-objects on the backplane. The micro-assembler backplane also has at least one trap location that is separate from the plurality of electrodes. The at least one trap location is configured to hold, independently of activation of the controlled electrodes, at least one micro-object that is manipulated into a trap location.

What is also disclosed is a micro-assembler apparatus that includes a micro-assembler backplane location that is configured to hold a micro-assembler backplane arrangement that has a micro-assembler backplane with a first surface; a number of controlled electrodes arranged in proximity to the first surface of the backplane to manipulate micro-objects on the micro-assembler backplane; and at least one trap location that is separate from the plurality of controlled electrodes. The at least one trap location is configured to hold, independently of activation of the controlled electrodes, at least one micro-object that is manipulated into a respective trap location. The micro-assembler apparatus also includes a micro-object location sensor configured to capture an image of a side of the micro-assembler backplane onto which micro-objects are placed and an electrode controller configured to, when operating, control which controlled electrodes are activated. The micro-assembler apparatus also includes a controller that is configured to, when operating: receive images from the micro-object location sensor where the images comprise images of micro-objects on the first surface of the micro-assembler backplane; determine a next control electrode pattern to create an electric field across the first surface of the backplane to manipulate at least one of a respective position or respective orientation of at least one micro-object on the first surface of the micro-assembler backplane; and control the electrode controller to activate controlled electrodes according the next controlled electrode pattern.

What is further disclosed is a method for assembling products containing micro-objects that includes placing, on a surface of a micro-assembler backplane arrangement, a number of micro-objects. The micro-assembler backplane arrangement includes a number of controlled electrodes arranged in proximity to a surface of the micro-assembler backplane arrangement; and at least one trap location that is separate from the plurality of controlled electrodes, where the at least one trap location is configured to hold, independently of activation of the plurality of controlled electrodes, at least one micro-object that is manipulated into a respective trap location. The method also includes receiving an image of the surface of the micro-assembler backplane arrangement where the image comprises images of the plurality of micro-objects. The method further includes determining, based on processing of the image, manipulations to be made to at least one of a respective location and a respective orientation of at least one micro-object in the plurality of micro-objects; controlling the controlled electrodes on the micro-assembler backplane to activate controlled electrodes on the micro-assembler backplane to create electric fields to perform the manipulations; and causing, based on the manipulations, a respective micro-object to be held in a respective trap location on the micro-assembler backplane.

Features and advantages of the above-described apparatus and direct-to-object print system will become readily apparent from the following description and accompanying drawings.

### BRIEF DESCRIPTION OF THE DRAWINGS

The foregoing and other features and advantages of the subject matter disclosed herein will be made apparent from the following detailed description taken in conjunction with the accompanying drawings, in which:

FIG. 1 illustrates a micro-assembler station, in accordance with an example;

FIG. 2 is a diagram depicting a view of an underside of a micro-assembler backplane, according to an example;

FIG. 3 illustrates a first alternative trap electrode configuration, according to an example;

FIG. 4 illustrates a second alternative trap electrode configuration, according to an example;

FIG. 5 illustrates a first trap power connection, according to an example;

FIG. 6 illustrates a second trap power connection, according to an example;

FIG. 7 illustrates a first physical feature trap location cross-section, according to an example;

FIG. 8 illustrates a second physical feature trap location cross-section, according to an example;

FIG. 9 illustrates an opposing surface micro-assembler backplane configuration, according to an example;

FIG. 10 illustrates a micro-assembler backplane assembly side view, according to an example;

FIG. 11 illustrates a micro-assembler backplane assembly bottom view, according to an example;

FIG. 12 illustrates a pipelined micro-assembler system, according to an example;

FIG. 13 illustrates a micro-object assembly process flow, according to an example; and

FIG. 14 illustrates a block diagram illustrating a processor, according to an example.

### DETAILED DESCRIPTION

### Non-Limiting Definitions

A “Micro-assembler apparatus” includes any configuration of equipment that has one or more stations that are adapted to process or perform any operation associated with assembling micro-objects onto a backplane.

A “Micro-object” is a small object or particle that may be used for various purposes in the manufacture and construction of various devices. Some assembly processes place a number of micro-objects into particular locations on a micro-assembler backplane.

A “Micro-assembler” is a manufacturing apparatus that operates to place one or more micro-objects into selected locations on a surface, such as a micro-assembler backplane.

A “Backplane” in the context of the following discussion is a substrate onto which micro-objects are able to be placed and manipulated into selected locations.

A “Micro-assembler backplane” is a backplane that is also equipped with elements that operate with a micro-assembler to manipulate micro-objects placed thereon.

A “Micro-assembler backplane arrangement” in the context of the following discussion generally refers to any structure that includes one or more backplanes that are able to support operations of a micro-assembler.

A “Micro-assembler backplane location” generally refers to any location into which a micro-assembler backplane or micro-assembler backplane arrangement is able to be located in order to support operations thereon.

An “Electrode” in this context is an element adapted to create an electric force when a voltage is applied thereto.

A “Controlled electrode” in the following discussion generally refers to any electrode that is controlled to generate a controllable electric field. Controlled electrodes are able to be activatable to manipulate micro-objects on a micro-assembler backplane.

“Activation” of a controlled electrode” includes, without limitation, causing any electrode to generate an electric field, including but not limited to applying a voltage to the controlled electrode via any type of switch to cause an electric field to be generated by the electrode.

An “Electrode Controller” broadly refers to any controller that is able to control activation of a controlled electrode such as by switching a voltage potential to that controlled electrode by any suitable technique.

A “Light activated switch” broadly refers to any electrical switch that varies its electrical conductance based on light impinging on at least a part of the light activated switch.

A “Target location” on a backplane is one of generally several particular areas on the surface of the backplane into which a micro-object is intended to be placed as part of a micro-assembly process.

A “Trap location” on a backplane is a type of “target location” that is designed to hold micro-objects in the target location independently of the activations of electrodes that move micro-objects into the trap locations.

A “Constantly active voltage” broadly refers to any provided voltage pattern that is generally present. In various examples, a constantly active voltage is able to be a DC voltage, an AC voltage, or a combination of these. A constantly active voltage includes in some examples a voltage waveform that is a time varying waveform. In some examples, the time varying waveform is able to cross or momentarily maintain zero volts during a longer time frame over which the constantly active voltage is present with a non-zero value.

“Holding a micro-object” refers to, without limitation, applying one or more forces by any suitable technique to a micro-object on a surface of a micro-assembler backplane in order to cause the micro-object to remain in its location.

“Manipulating micro-objects” generally refers to applying electric fields on a surface of a micro-assembler backplane to move or change one or both of that micro-object's position or orientation.

“Field electrodes” include electrodes that are part of a micro-assembler backplane that are removed from trap locations and are used manipulate micro-objects towards or into trap locations.

A “Trap adjacent electrode” is an electrode of a micro-assembler backplane that is located adjacent to a trap location and is adapted to create an electric field to efficiently manipulate micro-objects into an adjacent trap location. For example, a trap adjacent electrode is able to have a shape, thickness, other characteristics, or combinations of these, that are different from more remote field electrodes and that are selected to generate electric fields calculated to better manipulate micro-objects into its adjacent trap location. In some examples, other electrodes, such as other trap adjacent electrodes, are able to be located between a trap adjacent electrode and its adjacent trap location.

“Selective activation” of an electrode includes a controlled application of an electrical potential to the electrode in order to cause the electrode to produce a particular electric field. In some examples, an electrode is able to be selectively activated into one of a number of different states by having one of a number of different potentials applied by a controller to effect a change in the electric field generated by the electrode.

A “Variable light pattern” is a light pattern that varies with time and in the following context is used to illuminate an array of light activated switches.

A “Controller” is a device that is able to perform functions to control equipment based on one or more of programming, received inputs, prior control actions, other factors, or combinations of these.

A “Micro-object location sensor” is any sensor device or apparatus that is able to detect locations of micro-objects within its range. In general, a micro-object location sensor is able to use any technique to determine locations of micro-objects.

“Images from a micro-object location sensor” include any dataset that includes information indicating locations of micro-objects without regard to the format of that information or how the location information is indicated.

“Receiving an image from a micro-object location sensor” or “receiving an image of the surface of the micro-assembler backplane” includes receiving, from any sensor device, data representing physical locations of micro-objects within a range of that sensor device. In general, images that contain images of micro-objects on the first surface includes any dataset that includes information indicating locations of micro-objects on the surface of a backplane, regardless of methods and technologies used to obtain that location data.

“Determining a plurality of light patterns” or “determining a next light pattern” includes determining a light pattern to be projected onto or otherwise illuminate an array of light activated switches, such as phototransistors, to cause electrodes connected to those light activated switches to create electric fields that manipulate micro-objects on a surface of a micro-assembler backplane.

A “Light emitting device” in the context of the below description is a controllable light emitting device that is able to create and emit light patterns in a field defined by control in puts to the light emitting device.

A “Micro-assembler apparatus loading stage” in the following context is a processing stage adapted to place micro-objects onto a micro-assembler backplane in preparation for manipulation of those objects to their target locations.

An “Assembly stage” in the following context is a processing stage adapted to manipulate micro-objects on a micro-assembler backplane into their target locations.

A “Light activated electrode” in the following context is an electrode that is activated, e.g., is caused to generate a different electric field, by illuminating a light activated switch connected to that electrode.

The below described systems and methods are directed to operations of, and components used in, micro-assemblers. Micro-assemblers in some examples are a type of manufacturing equipment that operates to assemble products containing micro-objects by placing one or more micro-objects into defined locations on a surface. Micro-objects in some examples are small objects or particles that may be used for various purposes in the manufacture and construction of various devices. In some examples in the context of the following description, a micro-object is able to be any small object that is to manipulated on a surface or other structure.

In some examples, a micro-object can be an object that ranges in size from less than 1 micrometer to over 500 micrometers. In some examples, a micro-object is able to be much smaller than one micron, or have at least one dimension smaller than a micron, such as a wire or rod that is, for example, 10 μm long but that has a 0.1 μm diameter. In some examples, the below described systems and methods are able to be used to manipulate a heterogeneous mixture of different sizes of micro-objects. In order to facilitate placement of the micro-objects on the surface, the micro-objects in some examples are also able to be charge encoded micro-objects or magnetic field pattern encoded micro-objects. For example, a micro-object may have a positive charge, may be charged with a specific pattern, may be encoded with a particular charge or magnetic field pattern, or combinations of these.

In the following description, a device that has a surface adapted for use in a micro-assembler and incorporating the below described systems and methods is referred to as a micro-assembler backplane. In some of the below described examples, micro-objects are manipulated on a surface of a micro-assembler backplane upon which they are to be placed by electrical potentials induced by conductive elements, referred to below as electrodes, that are placed on or in the micro-assembler backplane. In examples, these conductive elements are arranged in a manner similar to pixels across a display, i.e., in an array across the surface onto which micro-objects are to be placed. In various examples, such arrangements are able to be uniform or, irregular, or a combination of both.

These conductive elements are able to be selectively activated by any suitable technique that creates an electric field on the surface of a micro-assembler backplane on which the micro-objects are placed. In an example, an electrical potential is able to be placed on an electrode in the micro-assembler backplane by activating a light activated switch, such as a phototransistor, that connects a voltage source to that electrode. In an example, a micro-assembler backplane is able to have a configurable, time varying, electrical potential field applied across its array of electrodes by controlling a corresponding array of phototransistors that connect each electrode to a voltage source. In an example, this array of phototransistors is able to be arranged on or within the micro-assembler backplane, such as on a surface that is opposite the surface onto which micro-objects are placed. Selective activation of electrodes in such an example is able to be achieved by illuminating the array of phototransistors with a variable light pattern that varies with time to illuminate selected phototransistors to cause a corresponding time varying electric field to be generated on the surface of the micro-assembler backplane on which micro-objects are placed. This configurable and time varying electrical potential allows micro-objects to be moved and placed along the surface of the micro-assembler backplane by selectively projecting variable light patterns that are optical image control patterns.

A selected set of phototransistors, when exposed to light, are able to be used to switch one or more of a positive voltage, a negative voltage, and an AC voltage, to charge selected electrodes on the surface of the micro-assembler backplane. In an example, each of those electrodes contain a conductive element that is able to generate one or more of dielectrophoretic (DEP) and electrophoretic (EP) forces on the surface onto which micro-objects are to be placed. The DEP and EP forces may be used to manipulate single micro-objects or groups of micro-objects that may comprise functionally identical or distinct micro-objects.

Using a variable light pattern containing a control pattern to Illuminate selected phototransistors allows the micro-assembler to precisely and quickly manipulate micro-objects and place them or orient them in specific locations, shapes, or patterns. Control patterns which are able to be formed by an optical image that is projected onto the phototransistor array may be used to control the phototransistors or other devices that are able to control or generate an electric field (e.g., electrodes, transistors, phototransistors, capacitors, etc.). Control patterns contained in the variable light pattern in some examples indicate a voltage pattern that is to be formed across at least a portion of the micro-assembler surface. Utilizing a light emitting device to generate optical image control patterns or voltage patterns allows a computing device to automatically form or place micro-objects into shapes or patterns. A camera or other micro-object location sensor is able to be used to determine the position and orientation of micro-objects on a micro-assembler surface such as by processing an image captured of that surface by a camera. In further examples, other devices may be used to detect the positions and orientations of micro-objects on the micro-assembler surface.

The below described systems and methods provide techniques to improve the efficiency and operation of micro-assembler operations. Below are described micro-assembler backplanes that incorporate features to cause micro-objects to remain in selected locations on the micro-assembler surface once they are manipulated into those positions. In conventional micro-assembler designs that use light patterns projected onto a phototransistor array to create the electrical potentials to hold the micro-objects in place, a fixed position light pattern sequence is projected onto the phototransistor array to cause the micro-objects that are in their desired position to remain in that position. Maintaining this fixed position light pattern sequence in some examples of conventional designs results in added complexity for the manufacturing process and limits flexibility in moving the micro-assembler surface between processing stations. In processing larger micro-assembler surfaces, a micro-assembler station will have added complexity to include equipment to maintain the fixed position light pattern sequence on phototransistors controlling the electric fields in areas of the micro-assembler surface where all the target locations have been filled with correct micro-objects with specified accuracy.

The below systems and methods allow a more simplified and flexible micro-assembler operation by including an ability to maintain the respective positions and orientations of micro-objects that have been properly placed into their target locations on a surface of a micro-assembler backplane. These systems and methods in some examples include structures to maintain the position of properly placed micro-objects without projecting a light pattern. Such systems and methods allow a simpler apparatus to project light patterns over a smaller section of the phototransistor array associated with the surface of the micro-assembler backplane and allows that simpler apparatus to manipulate micro-objects on different portions of a larger micro-assembler backplane over time while maintaining the position and orientation of already placed micro-objects. In some examples, the below systems and methods allow for a micro-assembler backplane onto which micro-objects have been properly placed to be more easily removed from one processing station and moved to another processing station where further processing steps can be performed on that micro-assembler surface.

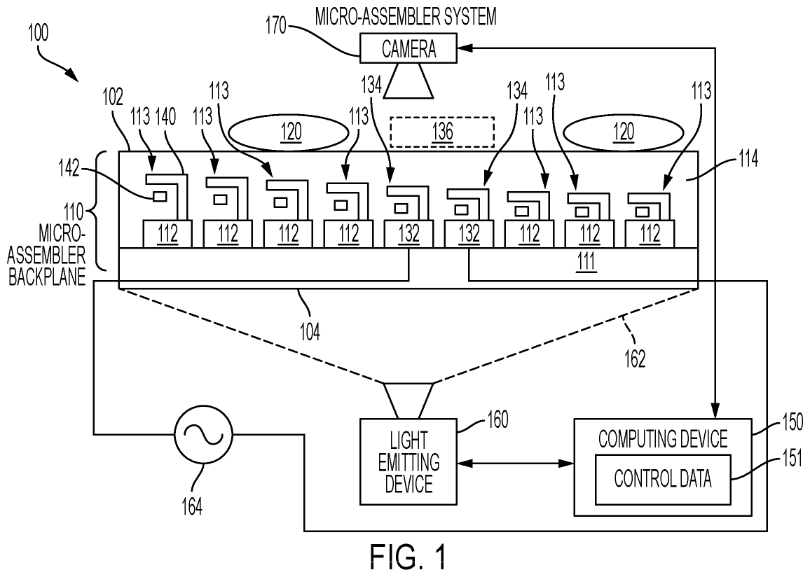

FIG. 1 illustrates a micro-assembler station 100, in accordance with an example. The micro-assembler station 100 depicts an example of a micro-assembler assembly stage, also referred to as an assembly stage, that is an example of an apparatus for controlling placement of micro-objects 120 onto a surface 102 of a micro-assembler backplane 110. The micro-assembler backplane 110 is an example of a micro-assembler backplane arrangement. The surface 102 is referred to as a first surface in the following description. The micro-assembler station 100 is shown with a micro-assembler backplane 110 that is positioned in a micro-assembler backplane location that is associated with the micro-assembler station 100 where that location is an operating position that allows interoperation with a light emitting device 160 and a camera 170. A computing device 150 is an example of a controller and in an example controls the light emitting device 160 and receives images from the camera 170 as is described below. The micro-assembler station 100 operates to move, hold in place, or control the placement (e.g., control one or more of the position or orientation) of the micro-objects 120 on the surface 102 of the micro-assembler backplane 110 using techniques described below.

In an example, the micro-assembler backplane 110 is a separable component that is placed into a location that is an operating position within the micro-assembler station 100 in order to be acted upon by the other components of the micro-assembler station 100. In some examples, the micro-assembler backplane 110 is able to be removed from and relocated away from the other components of the micro-assembler station 100. Such relocations can be made in order to, in some examples, allow the micro-assembler backplane 110 to be positioned to operate with other devices such as other processing stations, as is described below.

The illustrated micro-assembler backplane 110 includes a substrate layer 111 and a dielectric layer 114. In this example, the dielectric layer 114 has a number of phototransistors 112 and electrodes 113 located therein. In some examples, one or more of the phototransistors 112, electrodes 113, or both, are able to be formed on the substrate layer 111. The electrodes 113 in various examples are arranged in proximity to the first surface 102 of the micro-assembler backplane 110 and in some examples on top of or beside the phototransistors 112. In various examples, the substrate layer 111 is able to be a glass substrate or made of another material and has a bottom 104 onto which light patterns are able to be projected. The dielectric layer 114 in some examples is made of a material that is an electrical insulator.

In some examples, the light emitting device 160 is an example of an electrode controller that, in this example, operates to activate controlled electrodes by shining a variable light pattern 162 onto the bottom 104 of the micro-assembler backplane 110 and thereby illuminates one or more of the phototransistors 112 within the micro-assembler backplane 110. These phototransistors 112 are examples of light activated switches that control activation a respective electrode 113 connected to that phototransistor 112 to manipulate micro-objects on the backplane 110. The illustrated electrodes 113 are examples of controlled electrodes that are activatable to manipulate micro-objects and thus are able to be selectively activated to generate electric fields to cause manipulation, e.g., controlled movement, of micro-objects on the surface 102. The light emitting device 160 in various examples is able to be a device that is capable of emitting or transmitting a variable light pattern 162 that is projected onto the bottom of the micro-assembler backplane 110. In an example, the computing device 150 controls and varies the definition of the variable light pattern 162 so as to illuminate selected phototransistors 112 and not illuminate other phototransistors 112. In various examples, the light emitting device 160 is able to emit light that is visible light (e.g., white light), collimated light, or non-visible light (e.g., infrared (IR) light, ultraviolet (UV) light, etc.). For example, a light emitting device 160 may be a red LED or laser, a green LED or laser, a UV LED or laser, an IR LED or laser, a broadband halogen, fluorescent or halogen lamp, etc. The light emitting device 160 is able to include a patterning device, such as a digital projector (DLP) or liquid crystal panel (not shown). The substrate layer 111 in various examples is able to be transparent or semi-transparent in a wavelength range of the variable light pattern 162 emitted by the light emitting device 160. The variable light pattern 162 in various examples, as is described below, is able to control elements in the micro-assembler backplane 110 to cause those elements to manipulate the micro-objects 120.

In some examples, each phototransistor 112 is a semiconductor device that operates to switch an electric current between “off” and “on” based on being illuminated by light, such as light that is present in the variable light pattern 162. In further examples, other electrical switching devices are able to be used in place of, or in addition to, one or more of the illustrated phototransistor 112. In the illustrated example, a first terminal of phototransistor 112 is coupled to an electrode 113. In the illustrated example, each electrode 113 includes a first conductor 140 and a second conductor 142. In an example, the second conductor 142 of each electrode in an example is connected to a ground conductor (not shown) that is at a ground electrical potential. In such an example, another terminal of each phototransistor 112 is connected to a supply voltage conductor (not shown). In further examples, subsets of the phototransistors 112 and electrodes 113 within the micro-assembler backplane 110 are able to be connected to conductors that have different voltage sources. Each electrode 113 operates to store electrical signals switched by the phototransistors 112 for a certain time period as a respective electric field that is present in the vicinity of the electrode 113. In further examples, it is understood that a micro-assembler backplane 110 is able to be designed to include alternative structures in place of the electrodes 113 to similarly create an electric field on the surface 102.

In various examples, the supply voltage conductor (not shown) to which one terminal of each phototransistor 112 is able to have one connection that is connected to a negative DC voltage, a positive DC voltage, or an alternating current (AC) voltage. When a phototransistor 112 is switched on, it then applies that positive, negative, or AC voltage to the electrode 113. The voltages applied to the electrode 113 in various examples generates one or more of dielectrophoretic (DEP) forces, electrophoretic (EP) forces, or both, that act upon the micro-objects 120 in the vicinity of that electrode 113. The DEP and EP forces that are exerted on the micro-objects 120 in various examples cause the micro-objects 120 to move around the surface 102 of the micro-assembler backplane 110. Thus, the dielectrophoretic (DEP) and electrophoretic (EP) forces are used to control the placement of micro-objects 120 on the surface of the micro-assembler backplane 110, as discussed in more detail below.

In various examples, the operation of the micro-assembler station 100 includes placing a number of micro-objects 120 in arbitrary locations on the surface 102 by any suitable technique. For example, a reservoir of tens, hundreds, thousands, tens of thousands, etc., of micro-objects 120 may be deposited onto the surface of the micro-assembler backplane 110. The number of micro-objects 120 may include micro-objects that are functionally identical or distinct. For example, the set of micro-objects may include 10 silica spheres and 100 gallium arsenide chips.

The micro-assembler station 100 then operates to reposition, reorient, otherwise manipulate, or combinations these, the micro-objects 120 on the surface 102 in order to cause a determined number of micro-objects to be placed into defined locations on the surface 102. An example of such an operation includes placing micro-object elements onto a video display panel as part of construction of such a video display panel.

In an example, the micro-assembler station 100 operates to determine a present location of the micro-objects 120 on the surface 102. In the illustrated example, the camera 170 captures images of the surface 102 along with the micro-objects 120 thereon, and provides those images to the computing device 150. In further examples, any type of micro-object location sensor is able to be used to determine locations of micro-objects on the surface 102. Image processing of those images by the computing device 150 identifies characteristics, such as location, orientation, other characteristics, or combinations of these, of each micro-object 120 located on the surface 102. In other examples, micro-object location sensors that measure other phenomenon, or combinations of physicals parameters, may be used in addition to or in place of camera 170 to determine the present location of the micro-objects 120 on the surface 102. In the present discussion, images that contain images of micro-objects on the first surface includes any dataset that includes information indicating locations of micro-objects on the surface of a backplane, regardless of methods and technologies used to obtain that location data. For example, the micro-assembler backplane can have built in sensors to detect the micro-objects, which could be advantage for very small objects where camera imaging is difficult.

Based on the determined present location of the micro-objects 120 on the surface 102, processing within the computing device 150 determined how the micro-objects are to be moved to place the micro-objects 120 into their desired locations. In an example, the computing device 150 determines a time sequence of force patterns to be applied to the micro-objects 120 across the surface 102 in order to move those micro-objects 120 into their desired locations. Processing within the computing device 150 then determines a time sequence of variable light patterns 162 where each variable light pattern 162 illuminates selected phototransistors 112 to create one of the force patterns in the time sequence of force patterns that are to be applied to the micro-objects 120. Determining this time sequence of variable light patterns includes determining a next light pattern to illuminate the light activated switches, e.g., the phototransistors in this example, to create an electric field across the first surface of the backplane to manipulate at least one of position, location, or both, of a micro-object on the first surface of the backplane.

Processing within the computing device 150 causes the light emitting device 160 to sequentially project the time sequence of variable light patterns 162 onto the back of the micro-assembler backplane 110, including the next light pattern. Sequentially projecting the time sequence of variable light patterns 162 onto the back of the micro-assembler backplane 110 is an example of selectively illuminating selected phototransistors 112 in order to cause their associated electrodes 113 to be activated and produce desired forces on the surface 102. In an example, a set of dynamic (e.g., varying or changing) EP and DEP forces are produced on the surface 102 by the variable light patterns 162 projected by the light emitting device 160.

In some examples, the computing device 150 receives information regarding the present location of the micro-objects 120 on the surface 102 as the time sequence of variable light patterns 162 are being projected. In one such example, the camera 170 provides images of the surface 102 to the computing device 150 at various times while the variable light patterns are being projected. Processing within the computing device 150 is able to determine the location of micro-objects 120 on the surface 102 while the micro-objects are being manipulated across the surface 102. Such determinations are able to be used to provide a feedback loop for the manipulation of the micro-objects whereby the computing device 150 is able to alter variable light patterns 162 in order to accommodate the actual position of micro-objects 120 on the surface 102.

In some examples, the computing device 150 causes the time sequence of variable light patterns 162 to be projected in an open loop process without analyzing the positions, locations, orientations, etc., of the micro-objects 120 as these variable light patterns 162 are projected. In such examples, the computing device 150 does not receive information about the positions, locations, orientations, etc., of the micro-objects 120 and thus does not operate with any feedback in generating the variable light patterns 162, and thus cycles through the variable light patterns based on a pre-determined order and a pre-determined timing between the control patterns (e.g., use the first control pattern for five seconds, then cycle to the next control pattern for ten seconds, etc.).

In some examples, the below described systems and method include a micro-assembler backplane 110 that overcomes limitations of conventional techniques that only provides electrical forces at points on a micro-assembler surface when a phototransistor corresponding to that point is illuminated by a light emitting device. In conventional examples, micro-objects are only retained in position when the light emitting device is illuminating the phototransistors associated with the locations in which the micro-objects are to be retained. This characteristic of conventional techniques complicates, for example, operations on micro-assembler backplanes that have large area since the whole area has to be illuminated to retain micro-objects in places they have already been placed. This characteristic also restricts an ability to be able to remove the micro-assembler backplane from the micro-assembler station while retaining the micro-objects in their desired locations. An example of removing the micro-assembler backplane 110 from the micro-assembler station 100 is a scenario where a micro-assembler backplane 110 has had micro-objects placed in locations specified for that micro-assembler backplane 110 is removed from one processing station and taken to another processing station to have a different processed performed on it.

The below described examples include micro-assembler backplanes 110 that have micro-object trap locations 136 located at the locations on the surface 102 where micro-objects are to be located for a particular manufacturing process. In an example, a trap location is a location that is separate from electrodes and on the first surface of the backplane and that is configured to hold, independently of activation of the plurality of light activated switches activating the other electrodes, at least one micro-object that is manipulated into that trap location. In various examples, particular micro-object backplanes are able to be constructed that have micro-object trap locations 136 located at the location at which micro-objects are to be located for a particular product being manufactured. In the case of different products that have different required locations for the micro-objects 120 on the surface 102, a particular micro-assembler backplane 110 is created for each desired micro-object arrangement on the surface 102, where a micro-object trap location is placed on the surface 102 for each desired micro-object location in the particular arrangement. Similarly, if different size products are to be assembled with similar distributions of trap locations, smaller products are able to be assembled by using only part of a micro-assembler backplane 110.

In addition to the above-described phototransistors 112 and electrodes 113, the illustrated micro-assembler backplane 110 includes a micro-object trap location 136. The following description includes one micro-object trap location 136 for simplicity and it is to be understood that any number of micro-object trap locations are able to be placed at various desired locations on the surface of 102 of the micro-assembler backplane 110.

The micro-object trap location 136 in various examples is a location on the surface 102 of the micro-assembler backplane 110 that is designed to hold one or more micro-objects 120 in place after it is manipulated into the micro-object trap location 136. In general, micro-object trap locations 136 are able to have a variety of designs. The illustrated micro-object trap location 136 includes two micro-object trap elements that each have a trap transistor 132 that is connected to a respective trap electrode 134. In the illustrated example, the two trap transistors 132 are each conductively connected to one side of a trap voltage supply 164. The trap voltage supply 164 in this example causes a continuously active voltage to be applied to the trap electrodes 134 which results in a continuously active electric field being present in the micro-object trap location 136 that thus causes a micro-object 120 in that vicinity to be held in place. In various examples, the trap voltage supply 164 generates a continuously active voltage that has a constant profile and thus creates a persistent electric field, but the trap voltage supply in various examples is able to generate one of a DC voltage, an AC voltage, or a combination of these. Because the trap voltage supply 164 is connected to the trap transistors 132, that force is present regardless of whether or not the variable light pattern 162 is illuminating that area of the micro-assembler backplane 110. This causes micro-objects 120 that are located within the micro-object trap location 136 to be held in that location independently of the variable light pattern 162 projected on to the phototransistors 112.

The illustrated micro-assembler backplane 110 depicts trap electrodes 134 that are electrodes that have a structure similar to the electrodes 113 connected to the phototransistors 112. In further examples, as are described below, the trap electrodes 134 are able to be any suitable structure to create the electric fields used to hold a micro-object 120 into the micro-object trap location 136.

The illustrated micro-assembler backplane 110 depicts one micro-object trap location 136 that consists of two trap transistors 132 and their connected trap electrodes 134. In general, a micro-assembler backplane 110 is able to include any number of micro-object trap locations 136 that are able to be placed at any location around the surface 102 of the micro-assembler backplane 110. Further, a particular micro-object trap location 136 is able to have any number of trap transistors 132 and connected trap electrodes 134 arranged in any pattern around a particular micro-object trap location 136. In some examples, a micro-assembler backplane 110 is able to have a number of trap voltage supplies (not shown) of various voltages and different trap transistors 132 are able to be connected to trap voltage supplies of different voltages by suitable wiring or other interconnections (not shown) to different trap voltage supplies that produce different voltages.

In some examples, the incorporation of micro-object trap locations 136 on the surface 102 allows micro-objects 120 to be held in the micro-object trap locations 136 without applying a variable light pattern 162. This allows the micro-assembler station 100 to operate on only a sub-portion of the micro-assembler backplane 110 at a time. In an example, the depicted micro-assembler backplane 110 is a portion of a larger micro-assembler backplane where the depicted equipment, such as the light emitting device 160 and camera 170, operate on only a portion of the larger micro-assembler backplane 110. Once micro-objects have been manipulated into the micro-object trap locations 136 that are within view of the camera 170 and areas of electrodes 113 that have phototransistors 112 within the view of the light emitting device 160, the light emitting device 160 and camera 170 are then able to be adjusted, such as by being repositioned, to process another portion of the larger micro-assembler backplane 110 without having to continue to provide a light pattern to the phototransistors where the micro-objects have already been placed into trap locations. As is described in further detail below, further examples include components attached to the micro-assembler backplane 110 to provide energy to the trap transistors when the micro-assembler backplane is removed from a station of the micro-assembler system.

The illustrated example depicts a phototransistor based micro-assembler hardware system which modulates the electric force field created by an array of electrodes. It is to be further understood that the principles described herein are readily applicable to other similar hardware systems where a force field is pixelated. For example, an electric force field is able to be created by a virtual capacitor, meaning they only exist while the light is on as is used in optoelectrofluidic systems utilizing an unpatterned photoconductor layer and a transparent electrode (as illustrated in “Optoelectronic Tweezers for Manipulation of Cells and Nanowires”, by Ming C. Wu, et al., Electron Devices Meeting 2007. IEDM 2007. IEEE International, pp. 847-850, 2007.). In another example the force generating pixels could be from electrically addressed electrodes, such as from an active matrix integrated circuit or other electronic control circuit. In some examples, the electric fields created across the surface of the micro-assembler system are able to be controlled by any suitable technique including techniques alternative to, or in conjunction with, the above described light control techniques. Other examples of addressable pixelated force fields could be based on magnetic or acoustic forces. A force generating pixel may refer to a component or device that may be capable of generating a force that may be exerted on one or more micro-objects.

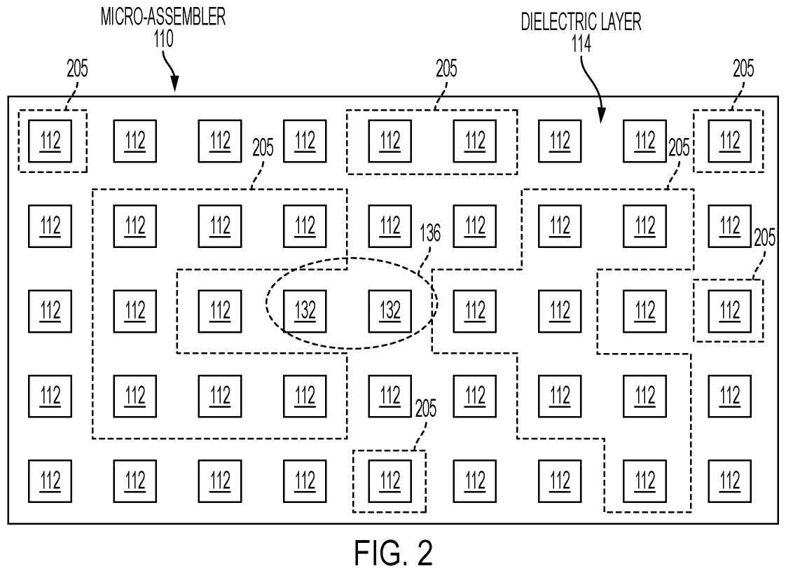

FIG. 2 is a diagram depicting a view of an underside of a micro-assembler backplane 200, according to an example. The underside of a micro-assembler backplane 200 refers the above description of the micro-assembler station 100 and is an example of a view of the above-described micro-assembler backplane 110 as viewed from the direction of the light emitting device 160.

The underside of a micro-assembler backplane 200 depicts an example of an array of phototransistors 112 that are arranged in an M×N matrix or an array, where M and N are two arbitrary numbers. In the illustrated example, the phototransistors 112 form a two-dimensional (2D) array. In an example, each phototransistor 112 (or each group comprising one phototransistor 112 and one electrode 113) may be referred to as a pixel.

The underside of a micro-assembler backplane 200 illustrates a number of control patterns 205, which are areas that are illuminated by the variable light pattern 162 discussed above. As discussed above, a time sequence of variable light patterns 162 are generated by the light emitting device 160 under the control of the computing device 150 in an example to cause micro-objects 120 to be manipulated across the surface 102. In an example, the different control patterns 205 are able to be projected all simultaneously, each projected in sequence, or a combination of these.

The underside of a micro-assembler backplane 200 illustrates the location of the micro-object trap location 136, which includes the two trap transistors 132 discussed above. The illustrated micro-assembler backplane 200 depicts one micro-object trap location 136 for simplicity of description and to depict relevant details. It is to be understood that in general, a particular micro-assembler backplane 200 is able to have any number of micro-object trap locations that are located at any chosen location on the surface 102 of the micro-assembler backplane 200. It is further to be understood that a particular micro-object trap location 136 is able to have any number of trap transistors 132 and connected trap electrodes 134

In some examples, the trap electrodes, such as the above-described trap electrodes 134, are able to have shapes in a plane parallel to the surface 102 of the micro-assembler backplane 110 that are similar to the shapes of the other electrodes in that micro-assembler backplane 110. In further examples, as are described in further detail below, the trap electrodes are able to have different shapes than the other electrodes. The design of such different shapes of the trap electrodes is able to be chosen to better tailor the shape of electric fields generated by those trap electrodes. The trap electrodes in some examples are able to be designed with a desired shape and size to match the target micro-objects that are to be held by them. In some examples, the shape of the electric fields forming the electrostatic trap, which is determined by factors such as the electrode size and shape in conjunction with the target micro-object, can be simulated and optimized in software.

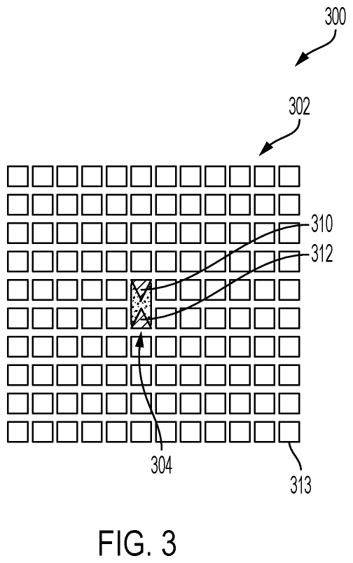

FIG. 3 illustrates a first alternative trap electrode configuration 300, according to an example. The first alternative trap electrode configuration 300 illustrates a view of the top surface of a first alternative micro-assembler backplane 302. The view illustrated in the first alternative trap electrode configuration 300 is similar to the view of the surface 102 of the micro-assembler backplane 110 that is observed by camera 170 described above.

The first alternative trap electrode configuration 300 shows a first alternative trap 304 made up of a first alternative electrode design with a first alternative first electrode 310 and a first alternative second electrode 312. Also shown are what are referred to as “field electrodes” 313, which are electrodes that are not located in trap locations and have square shapes in this example. These field electrodes 313 are similar to the electrodes 113 discussed above. As discussed above, the field electrodes 313 are controlled by various techniques, such as by the variable light pattern 162 discussed above, in order to manipulate the position, orientation, or both, of micro-objects to properly place micro-objects into trap locations such as the first alternative trap location 304. The shape of the trap electrodes 310 and 312 in the first alternative trap 304 have a different shape to reduce the possibility of having satellite local electrical potential minimums that will detrimentally impact the final assembly angle and location precision of micro-objects that are manipulated into the first alternative trap location 304.

Also shown are the square shape of the other electrodes 113 that are similar to the electrodes 113 discussed above. As discussed above, the other electrodes 113 are controlled by various techniques, such as by the variable light pattern 162 discussed above. The shape of these electrodes in the first alternative trap 304 have a different shape to reduce the possibility of having satellite local electrical potential minimums that will detrimentally impact the final assembly angle and location precision.

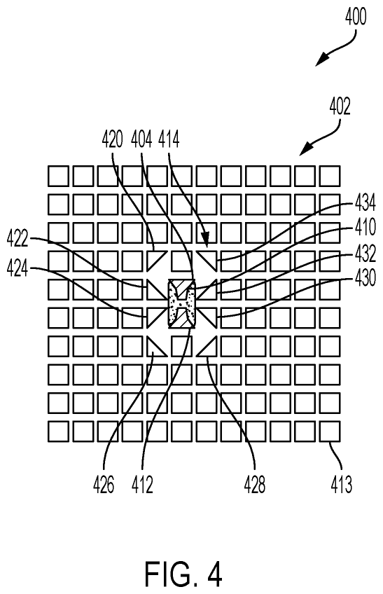

FIG. 4 illustrates a second alternative trap electrode configuration 400, according to an example. The second alternative trap electrode configuration 400 illustrates a view of the top surface of a second alternative micro-assembler backplane 402 that is similar to the view discussed above in the first alternative trap electrode configuration.

The second alternative trap electrode configuration 400 shows a second alternative trap 404 made up of a second alternative electrode design with a second alternative first electrode 410 and a second alternative second electrode 412. Also shown are the square shape of the field electrodes 413 in this example, which are similar to the electrodes 113 discussed above and are also similarly controlled. As discussed above, the field electrodes 413 are controlled by various techniques, such as by the variable light pattern 162 discussed above.

The second alternative trap electrode configuration 400 further has a number of trap adjacent electrodes 414 that are located adjacent to the second alternative trap 404. The trap adjacent electrodes 414 includes a first trap adjacent electrode 420, a second trap adjacent electrode 422, a third trap adjacent electrode 424, a fourth trap adjacent electrode 426, a fifth trap adjacent electrode 428, a sixth trap adjacent electrode 430, a seventh trap adjacent electrode 432, and an eighth trap adjacent electrode 434. The trap electrodes 410, 412 in the second alternative trap 404 and in the trap adjacent electrodes 414 have different shapes that have been selected, such as by computer simulations, to improve the accuracy and precision of placement and orientation in manipulating micro-objects into trap locations such as the second alternative trap 404. The illustrated example depicts field electrodes 413 that have a field electrode shape, e.g., square in this example, and further has at least one trap adjacent electrode that is located adjacent to a respective trap location and has a respective trap electrode shape that is different from the field electrode shape.

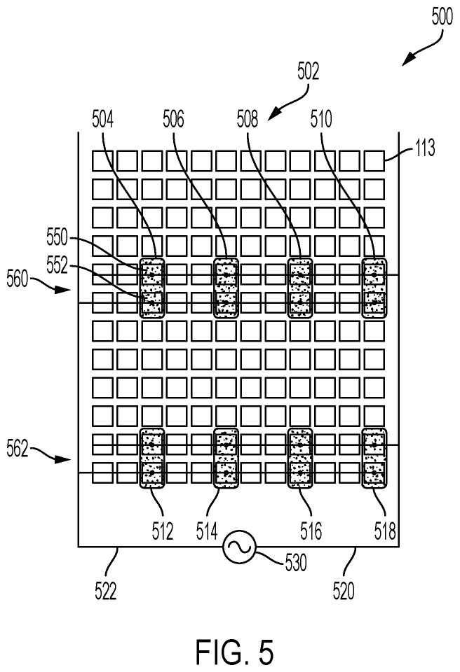

FIG. 5 illustrates a first trap power connection 500, according to an example. The first trap power connection 500 depicts a bottom view of a micro-assembler backplane 502 that has a number of trap locations. The micro-assembler backplane 502 illustrates trap locations that are arranged in two rows. A first row of trap locations 560 includes a first trap location 504, a second trap location 506, a third trap location 508, and a fourth trap location 510. A second row of trap locations 562 includes a fifth trap location 512, a sixth trap location 514, a seventh trap location 516, and an eighth trap location 518.

The first trap power connection 500 further illustrates a trap power supply 530 that provides a continuously active AC voltage and current to the trap electrodes. The trap power supply 530 provides a first AC voltage on a first trap power line 522 and a second AC voltage, which is of equal magnitude and 180 degrees out of phase with the first AC voltage, on a second trap power line 520. This arrangement depicts an example of a trap location that includes at least one respective trap electrode that is configured to have a continuously active voltage applied during activation of the plurality of light activated switches to hold at least one respective micro-object in the respective trap location.

Using the first trap location 504 as an example, the first trap location includes a first trap electrode 550 and a second trap electrode 552. The first trap electrode 550 is connected to the first trap power line 522 and the second trap electrode 552 is connected to the second trap power line 522. The other trap locations have similar electrode configurations and electrical connections. This arrangement causes all of the trap locations to have a continuously active electric field configuration that will act to hold micro-objects in those locations.

This configuration is simple to implement because it only needs one pair of conductors to connect between external circuitry, such as the trap power supply 530, all of the trap locations on the whole micro-assembler backplane 502. A limitation of this configuration, however, is that all of the trap locations use the same AC amplitude and waveform.

In some examples, it may be desirable to have different AC amplitude and waveforms applied to the two illustrated rows of trap locations. For example, the first row of trap locations 560 may be operating to receive micro-objects and performing a final “annealing” process, while the second row of trap locations 562 have micro-objects positioned into their final location and angle and their placement is within specifications. In such a case, the second row of trap locations 562 is able to operate to provide a maximum holding force to maintain the precision of the location and orientation of those micro-objects for various downstream process.

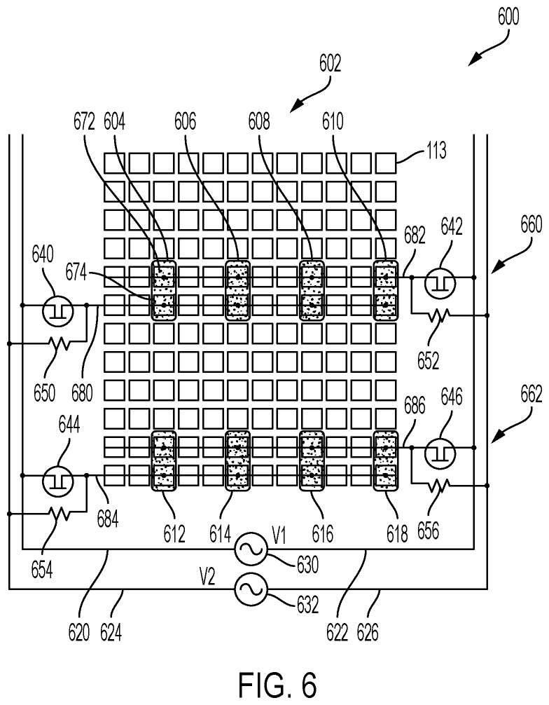

FIG. 6 illustrates a second trap power connection 600, according to an example. The second trap power connection 600 is similar to the first trap power connection 500 discussed above with the below described differences. The second trap power connection 600 depicts a bottom view of a micro-assembler backplane 602 that has a number of trap locations arranged in two rows. A first row of trap locations 660 includes a first trap location 604, a second trap location 606, a third trap location 608, and a fourth trap location 610. A second row of trap locations 662 includes a fifth trap location 612, a sixth trap location 614, a seventh trap location 616, and an eighth trap location 618.

As discussed above with regards to the first trap power connection 500 and using the first trap location 604 as an example, the first trap location 604 includes a first trap electrode 672 and a second trap electrode 674. The first trap electrode 672 is connected to a first row first electrode power line 682 and the second trap electrode 674 is connected to the first row second electrode power line 680. The other trap locations have similar electrode configurations and electrical connections where the first electrodes of the second row of trap locations 662 are connected to a second row first electrode power line 684 and the second electrodes of the second row are connected to the second row second power line 686.

The second trap power connection 600 includes two trap voltage supplies, a first trap voltage supply V1 630 and a second trap voltage supply V2 632. A first voltage first line 620 is connected to a first side of the first trap voltage supply V1 630 and a first voltage second line 622 is connected to the second side of the first trap voltage supply V1 630. A second voltage first line 624 is connected to a first side of the second trap voltage supply V2 632 and a second voltage second line 626 is connected to the second side of the second trap voltage supply V2 632.

In the illustrated example, the voltage applied to all of the trap locations in the same row can be selected between these two different voltage sources. In the illustrated example, the first row second electrode power line 680 is connected to the first voltage first line 620 via a first phototransistor 640 and to the second voltage first line 624 via a first resistor 650. The first row first electrode power line 682 is connected to the first voltage second line 622 via a first phototransistor 640 and to the second voltage second line 626 via a second resistor 652. The second row first electrode power line 684 is connected to the first voltage first line 620 via a third phototransistor 644 and to the second voltage first line 624 via a third resistor 654. The second row second power line 686 is connected to the first voltage second line 622 via a fourth phototransistor 646 and to the second voltage second line 626 via a fourth resistor 656.

In an example, the phototransistors of the first row of trap locations 660, i.e., the first phototransistor 640 and the second phototransistor 642, are illuminated, i.e., turned on, to apply the connect the first trap voltage supply 630 across the electrodes of the first row. In an example, this may be done when the first row of trap locations 660 is performing a process for which it is desired to have the voltage of the first trap voltage supply 630 applied to the trap electrodes, such as, e.g., during an annealing stage of the assembly. The voltage of the first trap voltage supply 630 is provided to the traps of the first row when those phototransistors are illuminated because the illuminated phototransistors have a higher conductivity than the first bias resistor 650 and the second bias resistor 652. When the first phototransistor 640 and the second phototransistor 642 are not illuminated, i.e., turned off, the first row second electrode power line 680 and first row first electrode power line 682 are connected to the second trap voltage supply 632 via the first bias resistor 650 and the second bias resistor 652.

In an example, the second row of trap locations 662 has micro-objects that are already located in the trap locations of the second row of trap locations 662 and are thus assembled according to specifications. In that example, the third phototransistor 644 and the fourth phototransistor 646 are not illuminated, thus causing the voltage of the second trap voltage supply 632 to be applied across the electrodes of the trap locations of the second row of trap locations 662.

In the illustrated example, the first trap voltage supply 630 has a moderate AC voltage level to create an electric potential trap to center the micro-objects located in each trap location, but not an overly strong electric potential to pin the micro-objects firmly at initial locations without the possibility of reposition to true potential minimum. The voltage level of the first trap voltage supply 630 can also be a more complicated voltage sequence that provides a simulated “annealing” function to encourage the micro-objects to move around slightly to find true potential minimum. In this example, to voltage level of the second trap voltage supply 632 is able to be a high amplitude AC voltage that operates to create a strong pin down force to ensure the micro-objects do no not move around. This arrangement depicts an example of at least one light activated switch 640, 642 that is a trap location activation switch that selects a selected potential from within the plurality of potentials to apply, e.g., V1 630 and V2 632 in this example, to activate trap electrodes. This is further an example where that at least one trap location activation switch is a light activated switch, e.g., phototransistors 640 642 in this example.

The optical transistor and the bias resistor at the end of each row of trap locations can be implemented using the thin film process used to create the phototransistors of each electrode 113, or only optical sensor is provided on the phototransistor substrate and connecting to external circuit for multiplexing by standard Chip-On-Film (COF) bonding or chip on glass technology. Several rows can be tied together to be selected by one optical sensor to reduce the external wiring density. The advantage of external multiplexing is that better source integrity can be expected because of higher quality switches that can be implemented using thin film process.

In further examples, micro-object traps are able to be realized by any suitable technique. In some examples, the trap locations are able to include physical features to further aid in retaining the placement of the micro-object into the trap location, as are described below.

In some examples, particular micro-assembler backplanes are built with trap locations places at locations in which micro-objects are desired to be place for the construction of a particular device. In some manufacturing environments, different micro-assembler backplanes are able to be built with trap locations at different places on the surface of the micro-assembler backplane that corresponds to the placement of micro-objects in the construction of different products. In further examples, a particular micro-assembler backplane is able to have a number of trap locations and a micro-assembler station is able to control that micro-assembler backplane so as to cause micro-objects to move to only a subset of trap locations. For example, a larger backplane is able to be controlled by a micro-assembler station place micro-objects into trap locations located on half of that micro-assembler backplane in order to place micro-objects for manufacturing of a smaller device. Alternatively, the micro-assembler station is able to cause micro-objects to be located at any subset of trap locations in order to support the creation of different devices that have micro-objects placed at different locations. In some examples, a micro-assembler backplane is able to selectively activate by any suitable technique the subset of trap locations that are to be the destinations for micro-objects. The foregoing is an example of a micro-assembler backplane that has a first number of trap location and wherein manipulations of micro-objects include manipulations to move respective micro-objects into a second number of trap locations within the first number of trap locations while leaving vacant trap locations in the first number of trap locations that are outside of the second number of trap locations. In such an example, causing the respective micro-objects to be held in a respective trap location includes holding the respective micro-objects in the second number of trap locations.

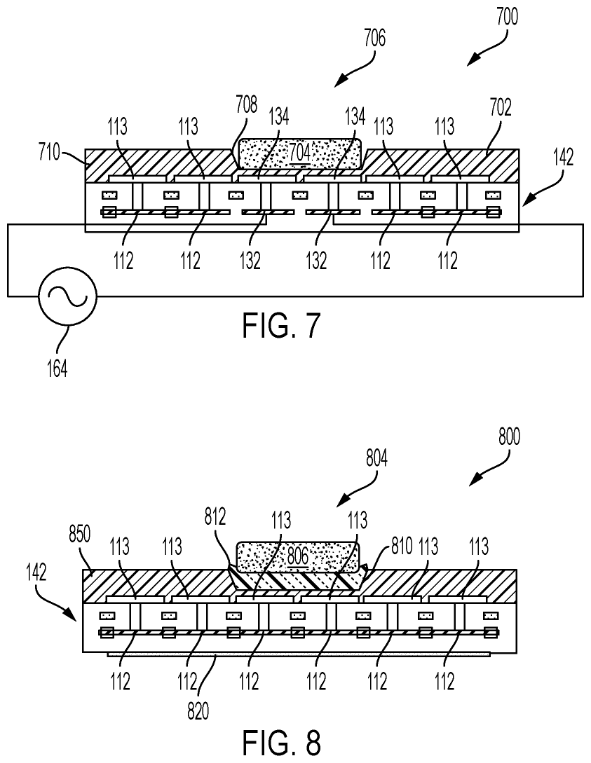

FIG. 7 illustrates a first physical feature trap location cross-section 700, according to an example. The first physical feature trap location cross-section 700 depicts an example of a trap location that includes a physical shape to assist in locating and retaining micro-objects.

The first physical feature trap location cross-section 700 depicts a micro-object backplane 710 that has a surface 702 with a depressed trap location 706 thereon. The depressed trap location 706 has a depression 708 that is an example of a depression on a first surface of a micro-assembler backplane. In the illustrated example micro-object 704 is located within the depression 708. In the illustrated example, the depression 708 is sized to match the size of the micro-object 704 in order to better facilitate the location and orientation of the micro-object 704 that is within the depression 708

The illustrated first physical feature trap location cross-section 700 depicts a number of electrodes 113 and phototransistors 112 that are similar to those similar elements described above with regards to the micro-assembler station 100. In the illustrated example, a trap electrodes 134, such as the above described trap electrodes 134, and trap transistors 132, such as the above described trap transistors 132, along with the above described connections for such elements are able to be located under a depressed trap location 706. As is discussed above with regards to the micro-assembler station 100, the trap electrodes 134 are connected to a trap voltage supply 164 to maintain a holding force. In such an example the trap electrodes and trap transistors are able to further provide holding forces for the micro-object within the depressed trap location 706 and also have the ability to continue to apply the holding force in the absence of an illumination 162. In an alternative example, electrodes 113 and phototransistors 112, which are activated by the variable light pattern 164, are located under the depressed trap location 706 and are similar to these elements that are located in the rest of the micro-object backplane 710. In an example, such electrodes 113 and phototransistors 112 located under the depressed trap location 706 in order to be selectively activated to, for example, move, e.g., pop off, a micro-object 704 that has erroneously moved into the depression 708.

FIG. 8 illustrates a second physical feature trap location cross-section 800, according to an example. The second physical feature trap location cross-section 800 depicts an example of a trap location that includes a physical shape to assist in locating and retaining micro-objects and further includes an adhesive material at the trap location.

Similar to the above described first physical feature trap location cross-section 700, the second physical feature trap location cross-section 800 depicts a micro-object backplane 850 that has a surface 802 with a depressed trap location 804 that includes a depression 810. In this example, the depression 810 is lined with a shape memory polymer 812 to trap a micro-object 806 that has been placed into the depressed trap location 804. The micro-object backplane 850 in this example includes a heater 820 that can be turned on and off by any suitable technique (not shown). The heater 820 operates to heat the shape memory polymer or alloy to above its phase transition temperature, e.g., ˜60° C., to become soft and tacky. When a micro-object 806 is placed in its desired location within the depressed trap location 804, the heater 820 is turned off and the micro-object 806 will adhere to the shape memory polymer 812 with a strong force as it cools to ambient temperature.

In further examples, a trap location is able to include, either alternatively or additionally, a chemically selective surface that operates to strongly bind to a micro-object that moves into that trap location. Examples of such chemically selective surfaces include selective biochemical binders that are used for biochemical assays and detection. The trap location is also able to include, either alternatively or additionally, a magnet that attracts a micro-object at or near the trap location. In some examples, trap locations are able to retain micro-object based at least in part by structures creating van der Waals forces with micro-objects.

In the illustrated example, the electrodes 113 and phototransistors 112 located under the depressed trap location 804 are similar to these elements that are located in the rest of the micro-object backplane 850. In an example, such electrodes 113 and phototransistors 112 located under the depressed trap location 804 in order to move, e.g., pop off, a micro-object 806 that has erroneously moved into the depression 810. In an alternative example, trap electrodes, such as the above described trap electrodes 134, and trap transistors, such as the above described trap transistors 132, along with the above described connections for such elements are able to be located under a depressed trap location 804. In such an example the trap electrodes and trap transistors are able to further provide electrostatic holding forces for the micro-object within the depressed trap location 804 to assist the adhesive holding force of the shape memory polymer 812 in the absence of illumination 162.

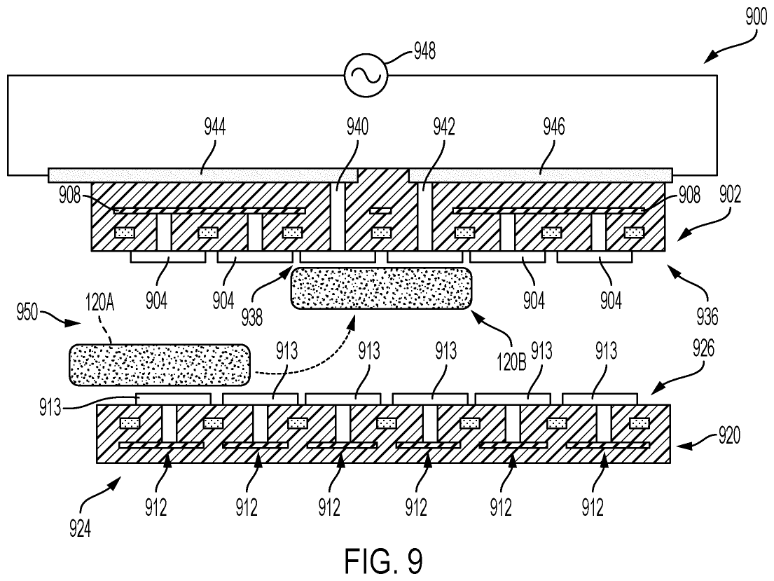

FIG. 9 illustrates an opposing surface micro-assembler backplane configuration 900, according to an example. The opposing surface micro-assembler backplane configuration 900 is an example of a micro-assembler backplane arrangement that includes an arrangement of a micro-assembler movement backplane 920 and a micro-assembler trap location backplane 902. The micro-assembler movement backplane 920 has a movement surface 926 that has a number of electrodes 913 that are light activated in a manner similar to the electrodes 113 of the above-described micro-assembler backplane 110. The electrodes 913 of the illustrated micro-assembler movement backplane 920 are also light activated by means of the phototransistors 912 and are able to be controlled by a micro-assembler station 100 in a manner similar to that discussed above. In the illustrated example, the phototransistors 912 are able to be illuminated via a bottom 924 of the micro-assembler movement backplane 920. In the illustrated example, the micro-assembler movement backplane 920 does not have trap locations, although alternative examples are able to include them.

The micro-assembler trap location backplane 902 has a trap surface 936 that is located opposite the movement surface 926 of the micro-assembler movement backplane 902. The trap surface 936 and the movement surface 902 form a gap 950 between the two surfaces. In some examples, the gap 950 is able to be on the order of one hundred micrometers (100 μM) or less. In various examples, the gap 950 is able to be any suitable size.

A trap location 938 is depicted on the trap surface 936 and has a set of trap electrodes consisting of a first trap electrode 940 and a second trap electrode 942. The first trap electrode 940 is electrically connected to a first output of a trap voltage supply 948 via a first trap power line 944, and the second trap electrode 942 is connected to a second output of the trap voltage supply 948 via a second trap power line 946. The tramp voltage supply 948 is similar to the above-described trap voltage power supply 164 and is able to provide any suitable voltage to support proper operations of the trap location 938.

The micro-assembler trap location backplane 902 has a number of trap surface electrodes 904 located on or near the trap surface 938. In an example, the trap surface electrodes 904 are all connected to a trap surface electrode potential conductor 908 that causes the trap surface electrodes 904 to be held to a common potential. In an example, the trap surface electrode potential conductor 908 is held to a ground potential. In further examples, the trap surface is able to have a contiguous ground plane at locations other than a trap location 938.

The illustrated opposing surface micro-assembler backplane configuration 900 depicts movement of a micro-object from an initial location, depicted as an initially placed micro-object 120A, into its determined position as a finally placed micro-object 120B in the trap location 938. In an example operation, micro-objects, such as a number of objects similar to the initially placed micro-object 120A, are placed into the gap 950 and the electrodes 913 of the micro-assembler movement backplane 920 are activated to cause the micro-objects to move across the movement surface 926 into locations underneath trap locations 938 on the trap surface 936. In an example, the trap electrodes at the trap location 938 are constantly activated and will cause micro-objects on the movement surface 926 in the vicinity of the trap location 938 to be moved into the trap location 938 as is shown by the finally placed micro-object 120B. In further examples, the trap electrodes are able to be selectively activated by any suitable technique. Once all of the micro-objects are placed into trap locations on the trap surface 936, the micro-assembler trap location backplane 902 is able to be moved from its operating position to support further processing. In an example, the micro-assembler trap location backplane 902 is able to be separated from the micro-assembler movement backplane 920 to further support further processing.

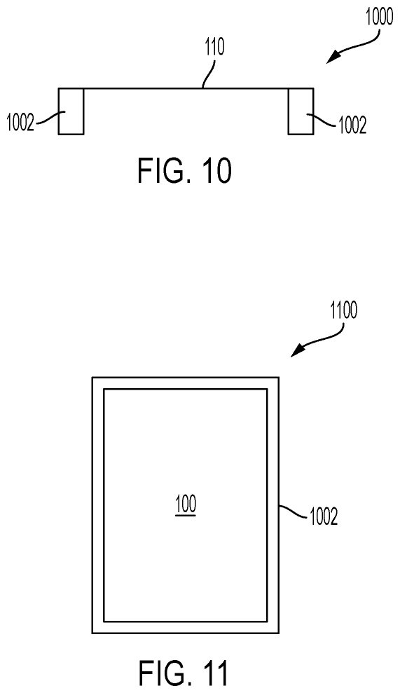

FIG. 10 illustrates a micro-assembler backplane assembly side view 1000, according to an example. In some examples, a micro-assembler backplane, such as the above-described micro-assembler backplane 110, is able to be moved between multiple processing stations to have different processing steps performed on it. In some examples, a micro-assembler backplane 110 is fitted with components that are able to maintain the trap voltages on the transistors controlling the trap electrodes, such as the trap electrodes. Such designs allow processing of the micro-assembler backplane 110 to properly place micro-objects into trap locations, and then the micro-assembler backplane 110 is able to be moved to other processing stations while retaining the micro-objects 120 in their desired locations.

The micro-assembler backplane assembly side view 1000 shows the micro-assembler backplane 110 with a support frame 1002. The support frame 1002 in an example contains the trap power supplies, such as the above-described trap power supply 530 or first trap voltage supply 630 and the second trap voltage supply 632. In some examples, such power supplies may include batteries or other energy storage devices to provide energy to energize the trap electrodes while the micro-assembler backplane 110 is moving between processing stations. In some examples, the support frame 1002 is also able to hold printed circuit boards, electronics, DC-DC converters or DC-to-AC converters to provide power to the trap transistors 132. In some such designs, a battery or other energy storage device within the support frame 1002 is able to be recharged when is it placed into a processing station.

FIG. 11 illustrates a micro-assembler backplane assembly bottom view 1100, according to an example. The micro-assembler backplane assembly bottom view 1100 is a bottom view of the micro-assembler backplane 110 depicted in the micro-assembler backplane assembly side view 1000 and illustrates the support frame 1002 structure along the outside of the micro-assembler backplane 110. In further examples, any suitable structure is able to be included as part of, attached to, otherwise associated with, or combinations thereof, a micro-assembler backplane 110 in order to provide the above-described functions provided by the support frame 1002.

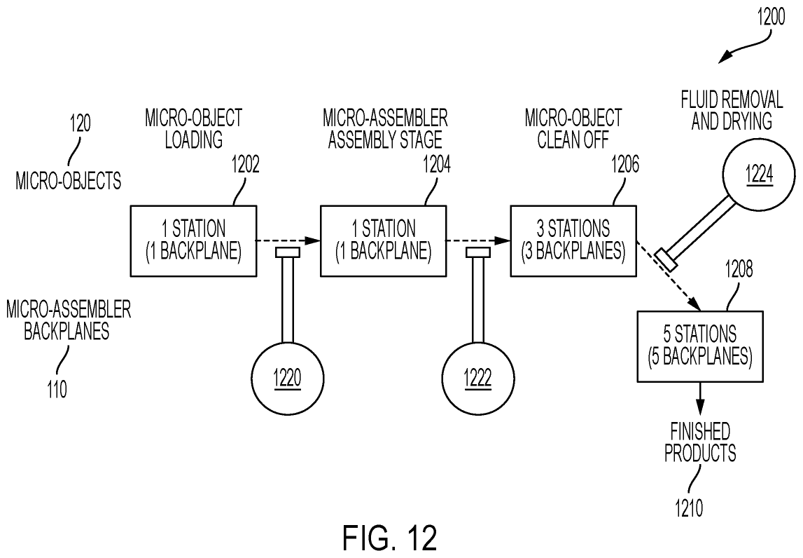

FIG. 12 illustrates a pipelined micro-assembler system 1200, according to an example. In an example, a pipelined micro-assembler system 1200 is a system that performs pipelined, parallel processing of micro-assembler backplanes in order to increase processing throughput.

The pipelined micro-assembler system 1200 is an example of a micro-assembler apparatus that depicts a four stage pipeline architecture for processing micro-assembler backplanes 110 in order to improve an overall throughput of the pipelined micro-assembler system 1200. In the pipelined micro-assembler system 1200, there are varying numbers of processing stations at each processing stage to accommodate the variable length of time used to perform the processing at the different processing stages that are performed on the micro-assembler backplane 110.

In the illustrated pipelined micro-assembler system 1200, micro-assembler backplanes 110 and micro-objects 120 are provided as inputs 1220. These inputs 1220 are provided to a micro-object loading stage 1202. In an example, the micro-object loading stage 1202 includes a micro-object feeder that is a source of micro-objects that are placed onto a micro-assembler backplane surface. A number of micro-objects 120 are placed onto the surface of the micro-assembler backplane 110 received at the input 1220. At this point, the micro-objects are generally not located at their desired locations on the micro-assembler backplane 110. In the illustrated example, the micro-object loading stage 1202 processes one (1) micro-assembler backplane at a time.

The pipelined micro-assembler system 1200 includes a first backplane movement device 1220 that moves the micro-assembler backplane 110 that has been loaded with micro-objects to the assembly stage 1204. In an example, the first backplane movement device 1220 includes a robotic arm that has an attachment mechanism to grab the micro-assembler backplane 110 located in the micro-object loading station 1202 and move that micro-assembler backplane 110, with the micro-objects loaded thereon but not located at their final position. In the assembly stage 1204 in an example, the micro-objects 120 are moved into their desired location and after the processing of this stage the micro-objects 120 are located in micro-object trap locations 136. After the processing of the assembly stage 1204, the micro-object trap locations 136 are activated to retain the micro-objects 120 into those locations. In an example power supplied by, e.g., components within the support frame 1002, provide power to activate the micro-object trap locations 136. In the illustrated example, the assembly stage 1204 processes one (1) micro-assembler backplane at a time.

The pipeline operation of the pipelined micro-assembler system 1200 allows the micro-object loading stage 1202 to operate on another micro-assembler backplane 110 by placing another set of micro-objects 120 thereon while the preceding micro-object backplane is being processed by at the assembly stage 1204. Such parallel operations operate to increase the overall throughput of the pipelined micro-assembler system 1200.

Micro-assembler backplanes 110 that have been processed by the assembly stage 1204 in the illustrated example are handled by a second backplane movement device 1222 for movement to an excess micro-object clean off stage 1206. The second backplane movement device 1222 in an example includes a robotic arm that is able to grab the micro-assembler backplanes 110 with an attachment mechanism to grab the micro-assembler backplane 110 located in the assembly stage 1204. In the illustrated example, the processing of micro-assembler backplanes 110 by the micro-object clean off stage 1206 takes three (3) times as long as the processing by the assembly stage 1204. In order to maintain efficient operation of the pipelined micro-assembler system 1200, the excess micro-object clean off stage 1206 is designed in this example to process three (3) micro-assembler backplanes in parallel. In an example, a cassette structure is used to hold the multiple micro-assembler backplanes 110 that are processed by the micro-object clean off stage 1206. In such an example, the second movement device 1222 places micro-assembler backplanes 110 into a holder, such as a cassette structure (not shown), as the micro-assembler backplanes 110 are removed from the assembly stage 1204. This cassette structure that is able to hold the three (3) micro-assembler backplanes that are processed in parallel by the micro-object clean off stage 1206 of this example. Loading the multiple micro-assembler backplanes 110 from the assembly stage 1204 into a cassette structure facilitates the movement of those multiple micro-assembler backplanes 110 by the second movement device 1222.

A third backplane movement device 1224 moves micro-assembler backplanes 110 processed by the excess micro-objects clean off stage 1206 to a fluid removal/drying stage 1208. In the illustrated example, the processing of micro-assembler backplanes 110 by the fluid removal/drying stage 1208 takes longer than the processing by the excess micro-object clean off stage 1206. In order to maintain efficient operation of the pipelined micro-assembler system 1200, the fluid removal/drying stage 1208 is designed in this example to process five (5) micro-assembler backplanes in parallel. In an example, a cassette structure is used to hold the multiple micro-assembler backplanes 110 that are being moved between the excess micro-object clean off stage 1206 to the fluid removal/drying stage 1208. In various examples, this cassette structure is able to include the cassette structure holding the three micro-assembler backplanes 110 that were processed by the excess micro-objects clean off stage 1206. In another example, the third backplane movement device 1224 is able to transfer micro-assembler backplanes from the cassette structure holding the three micro-assembler backplanes 110 processed by the excess micro-object clean off stage 1208 to another cassette structure that holds the five (5) micro-assembler backplanes 110 to be processed by the fluid removal/drying stage 1208, and then move that second cassette structure to the fluid removal/drying stage 1208.

The completed micro-assembler backplanes 110 are then provided as an output 1210 of the pipelined micro-assembler system 1200.

In the above example, micro-assembler backplanes 110 that have micro-objects placed in the micro-object trap locations 136 by the assembly stage 1204 will have those micro-object trap locations 136 energized while being moved between the assembly stage 1204 and the excess micro-objects clean off stage 1206 and then on to the fluid removal/drying stage 1208.

The example structure of the pipelined micro-assembler system 1200 illustrated above is based on the relative processing times of each processing stage. This pipelined architecture operates to reduce the difficulty of matching the process speed of each stage and thus improves system throughput. In an example, micro-assembler backplanes are conveyed between and among the various stations by a conveyor belt transfer apparatus that is able to operate in a manner analogous to a roller or belt transfer subsystem of laser printer.

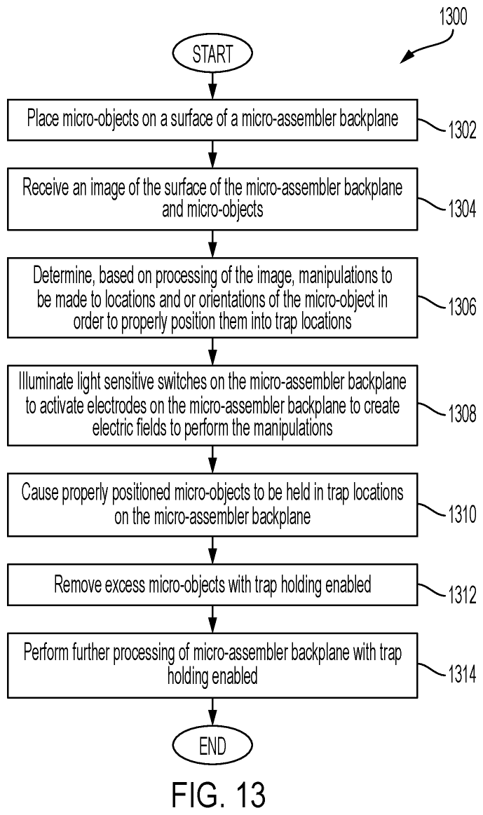

FIG. 13 illustrates a micro-object assembly process flow 1300, according to an example. The micro-object assembly process flow 1300 is an example of processing performed by the pipelined micro-assembler system 1200 described above.

The micro-object assembly process flow 1300 begins by placing, at 1302, micro-objects onto micro-assembler backplane. In an example, this is performed by the micro-object loading stage 1202 and is an example of placing, on a surface of a micro-assembler backplane, a plurality of micro-objects, wherein the micro-assembler backplane comprises a plurality of light activated electrodes and at least one trap location, separate from the plurality of light activated electrodes, the at least one trap location configured to hold, independently of activation of the plurality of light activated electrodes, at least one micro-object that is manipulated into a respective trap location within the at least one trap location.

The micro-object assembly process flow 1300 receives, at 1304, an image of the surface of the micro-assembler backplane and the micro-objects thereon. In various examples, this image is able to be captured by and received from any micro-object location sensor” such as a camera.

The micro-object assembly process flow 1300 determines, at 1306, manipulations to be made to locations and or orientations of the micro-object in order to properly position them into trap locations based on processing of the image. In an example, such a determination is made by the computing device 150 based on the above determined micro-object locations and the target locations into which the micro-objects are to be manipulated.

The micro-object assembly process flow 1300 continues in an example by illuminating, at 1308, light sensitive switches on the micro-assembler backplane to activate electrodes on the micro-assembler backplane to create electric fields to perform the above determined manipulations. This manipulation of micro-objects is performed in an example by processing within the assembly stage 1204. An example of performing these manipulations by illuminating light sensitive switches is described above as the manipulation of micro-objects 120 into micro-object trap locations 136. In an example, the above elements set forth manipulating micro-objects into locations of traps includes capturing an image of the surface of the micro-assembler backplane with the image also including images of the micro-objects; determining, based on processing of the image, manipulations to be made to at least one of a respective location and a respective orientation of the micro-objects; and illuminating light sensitive switches on the micro-assembler backplane to activate electrodes on the micro-assembler backplane to create electric fields to perform the manipulations.

The micro-object assembly process flow 1300 causes, at 1310, properly positioned micro-objects to be held in a respective trap location on the micro-assembler backplane. Based on the manipulations. Examples of causing a micro-object to be held in a trap location are discussed above and include one or more of manipulating the micro-object into a trap location that has trap electrodes with a continuously active voltage applied to them, into trap locations that have a depression to hold the micro-object, into trap locations that include a shape memory polymer, or combinations of these.

The micro-object assembly process flow 1300 removes, at 1312, excess micro-objects with trap holding enabled. In an example, removing the excess micro-objects is performed by the micro-object clean off stage 1206.

The micro-object assembly process flow 1300 performs, a 1314, further processing of micro-assembler backplane with trap holding enabled. In an example, such further processing includes moving, after causing the respective micro-object to be held in the respective trap location on the micro-assembler backplane, from the micro-assembler processing station to a subsequent processing station within a plurality of subsequent processing stations of a micro-assembler system. An example of such processing is the processing by the fluid removal and drying stage 1208. The micro-object assembly process flow 1300 then ends.

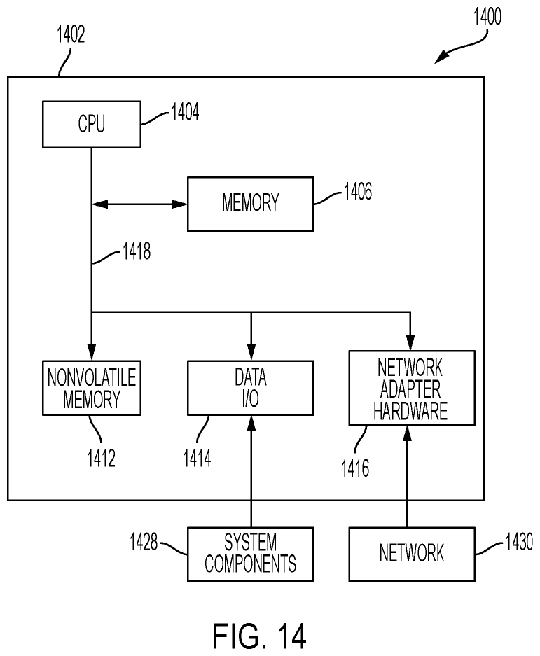

FIG. 14 illustrates a block diagram illustrating a processor 1400 according to an example. The processor 1400 is an example of a processing subsystem that is able to perform any of the above-described processing operations, control operations, other operations, or combinations of these.

The processor 1400 in this example includes a CPU 1404 that is communicatively connected to a main memory 1406 (e.g., volatile memory), a non-volatile memory 1412 to support processing operations. The CPU is further communicatively coupled to a network adapter hardware 1416 to support input and output communications with external computing systems such as through the illustrated network 1430.

The processor 1400 further includes a data input/output (I/O) processor 1414 that is able to be adapted to communicate with any type of equipment, such as the illustrated system components 1428. The data input/output (I/O) processor in various examples is able to be configured to support any type of data communications connections including present day analog and/or digital techniques or via a future communications mechanism. A system bus 1418 interconnects these system components.

### Information Processing System

The present subject matter can be realized in hardware, software, or a combination of hardware and software. A system can be realized in a centralized fashion in one computer system, or in a distributed fashion where different elements are spread across several interconnected computer systems. Any kind of computer system—or other apparatus adapted for carrying out the methods described herein—is suitable. A typical combination of hardware and software could be a general-purpose computer system with a computer program that, when being loaded and executed, controls the computer system such that it carries out the methods described herein.

The present subject matter can also be embedded in a computer program product, which comprises all the features enabling the implementation of the methods described herein, and which-when loaded in a computer system—is able to carry out these methods. Computer program in the present context means any expression, in any language, code or notation, of a set of instructions intended to cause a system having an information processing capability to perform a particular function either directly or after either or both of the following a) conversion to another language, code or, notation; and b) reproduction in a different material form.

Each computer system may include, inter alia, one or more computers and at least a computer readable medium allowing a computer to read data, instructions, messages or message packets, and other computer readable information from the computer readable medium. The computer readable medium may include computer readable storage medium embodying non-volatile memory, such as read-only memory (ROM), flash memory, disk drive memory, CD-ROM, and other permanent storage. Additionally, a computer medium may include volatile storage such as RAM, buffers, cache memory, and network circuits. Furthermore, the computer readable medium may comprise computer readable information in a transitory state medium such as a network link and/or a network interface, including a wired network or a wireless network, that allow a computer to read such computer readable information.

In general, the computer readable medium embodies a computer program product as a computer readable storage medium that embodies computer readable program code with instructions to control a machine to perform the above-described methods and realize the above-described systems.

What is claimed is:

1. A micro-assembler backplane arrangement, comprising:
a micro-assembler backplane having a first surface;
a plurality of controlled electrodes arranged in proximity to the first surface, wherein each controlled electrode in the plurality of controlled electrodes is selectively activatable to manipulate micro-objects on the micro-assembler backplane; and
at least one trap location, separate from the plurality of controlled electrodes, the at least one trap location configured to hold, independently of activation of the plurality of controlled electrodes, at least one micro-object that is manipulated into a respective trap location within the at least one trap location.

2. The micro-assembler backplane arrangement of claim 1, wherein the plurality of controlled electrodes comprises a plurality of light activated switches, where each light activated switch in the plurality of light activated switches controls activation of a respective controlled electrode in the plurality of controlled electrodes.

3. The micro-assembler backplane arrangement of claim 1, further comprising a trap surface, wherein the micro-assembler backplane comprises a movement surface that faces the trap surface and that is removed from the trap surface by a gap, wherein the trap surface comprises the at least one trap location.

4. The micro-assembler backplane arrangement of claim 1, wherein the plurality of controlled electrodes comprise a plurality of field electrodes having a field electrode shape, and further comprises at least one trap adjacent electrode, where each trap adjacent electrode is located adjacent to a respective trap location and has a respective trap electrode shape that is different from the field electrode shape.

5. The micro-assembler backplane arrangement of claim 1, where the at least one trap location comprises a depression in the first surface.

6. The micro-assembler backplane arrangement of claim 1, where the at least one trap location comprises at least one of a shape memory polymer, a chemically selective surface, or a magnet.

7. The micro-assembler backplane arrangement of claim 1, wherein each respective trap location in the at least one trap location comprises at least one respective trap electrode that is configured to have a continuously-active voltage applied during activation of the plurality of controlled electrodes to hold at least one respective micro-object in the respective trap location.

8. The micro-assembler backplane arrangement of claim 1, wherein each respective trap location in the at least one trap location comprises at least one respective trap electrode that is selectively activated by application of a selected potential selected from a plurality of potentials to the respective trap electrode of each trap location.

9. The micro-assembler backplane arrangement of claim 8, further comprising at least one trap location activation switch, each trap location activation switch selecting a potential from within the plurality of potentials to apply to the at least one respective trap electrode in the at least one trap location.

10. The micro-assembler backplane arrangement of claim 9, wherein the at least one trap location activation switch comprises a light activated switch.

11. A micro-assembler apparatus, comprising:
a micro-assembler backplane location configured to hold a micro-assembler backplane arrangement, where the micro-assembler backplane arrangement comprises:
a micro-assembler backplane having a first surface;
a plurality of controlled electrodes arranged in proximity to the first surface to manipulate micro-objects on the micro-assembler backplane; and
at least one trap location, separate from the plurality of controlled electrodes, the at least one trap location configured to hold, independently of activation of the plurality of controlled electrodes, at least one micro-object that is manipulated into a respective trap location within the at least one trap location;
a micro-object location sensor configured to capture an image of a side of the micro-assembler backplane onto which micro-objects are placed;
an electrode controller configured to, when operating, control which controlled electrodes are activated;
a controller that is configured to, when operating:
receive images from the micro-object location sensor, wherein the images comprise images of micro-objects on the first surface of the micro-assembler backplane;
determine a next controlled electrode pattern to create an electric field across the first surface of the micro-assembler backplane to manipulate at least one of a respective position or respective orientation of at least one micro-object on the first surface of the micro-assembler backplane; and
control the electrode controller to activate controlled electrodes according the next controlled electrode pattern.

12. The micro-assembler apparatus of claim 11, wherein the plurality of controlled electrodes comprises a plurality of light activated switches, where each light activated switch in the plurality of light activated switches controls activation of a respective controlled electrode in the plurality of controlled electrodes.

13. The micro-assembler apparatus of claim 11, further comprising a trap surface, wherein the micro-assembler backplane arrangement comprises a movement surface that faces the trap surface and that is removed from the trap surface by a gap, wherein the trap surface comprises the at least one trap location.

14. The micro-assembler apparatus of claim 11, wherein each respective trap location in the at least one trap location comprises at least one respective trap electrode that is selectively activated by a trap location activation switch that activates the respective trap electrode of each trap location by controlling application of a selected potential selected from a plurality of potentials; and
wherein the electrode controller is further configured to, when operating, activate the trap location activation switch.

15. The micro-assembler apparatus of claim 14, wherein the trap location activation switch comprises a light activated switch and wherein the electrode controller selectively causes the light activated switch to be illuminated.

16. The micro-assembler apparatus of claim 11, further comprising a backplane movement device configured to convey the micro-assembler backplane arrangement from at least one of into or out of the micro-assembler backplane location.

17. The micro-assembler apparatus of claim 16, further comprising:
a micro-object loading stage configured to, when operating, place a plurality of micro-objects onto a micro-assembler backplane arrangement; and
an assembly stage comprising the micro-assembler backplane location, the micro-object location sensor, the electrode controller, and the controller.

18. The micro-assembler apparatus of claim 17, wherein the backplane movement device is further configured to convey the micro-assembler backplane arrangement between the micro-object loading stage and the assembly stage.

19. A method for assembling products containing micro-objects, the method comprising:
placing, on a surface of a micro-assembler backplane arrangement, a plurality of micro-objects, wherein the micro-assembler backplane arrangement comprises a plurality of controlled electrodes arranged in proximity to a surface of the micro-assembler backplane arrangement; and at least one trap location, separate from the plurality of controlled electrodes, the at least one trap location configured to hold, independently of activation of the controlled electrodes, at least one micro-object that is manipulated into a respective trap location within the at least one trap location;
receiving an image of the surface of the micro-assembler backplane arrangement, the image comprising images of the plurality of micro-objects;
determining, based on processing of the image, manipulations to be made to at least one of a respective location and a respective orientation of at least one micro-object in the plurality of micro-objects;
controlling the controlled electrodes to activate controlled electrodes on the micro-assembler backplane to create electric fields to perform the manipulations; and
causing, based on the manipulations, a respective micro-object to be held in a respective trap location on the micro-assembler backplane.

20. The method of claim 19, wherein causing the respective micro-object to be held in a respective trap location comprises manipulating the respective micro-object into a depression within the respective trap location.

21. The method of claim 19, wherein causing the respective micro-object to be held in a respective trap location comprises manipulating the respective micro-object onto a shape memory polymer within the respective trap location.

22. The method of claim 19, further comprising placing the micro-assembler backplane arrangement into a micro-assembler backplane location of a micro-assembler processing station, the micro-assembler processing station comprising:
an electrode controller selectively activating the controlled electrodes on the micro-assembler backplane arrangement; and
a micro-object location sensor to capture the image of the surface.

23. The method of claim 22, further comprising moving, after causing the respective micro-object to be held in the trap location on the micro-assembler backplane, from the micro-assembler processing station to a subsequent processing station within a plurality of subsequent processing stations of a micro-assembler system.

24. The method of claim 22, wherein the at least one trap location comprises a first number of trap location,
wherein the manipulations comprise manipulations to move respective micro-objects into a second number of trap locations within the first number of trap locations while leaving vacant trap locations in the first number of trap locations that are outside of the second number of trap locations
wherein causing the respective micro-objects to be held in a respective trap location comprises holding the respective micro-objects in the second number of trap locations.

25. The method of claim 19, wherein causing the respective micro-object to be held in a respective trap location is based on an electric field present in the respective trap location that is maintained independently of activation of the plurality of controlled electrodes.

26. The method of claim 25, wherein the electric field present in the respective trap location is provided based on a power supply incorporated into the micro-assembler backplane.
